(19) United States
(12) Patent Application Publication
(10) Pub. No.: US 2026/0173299 A1
(43) Pub. Date: Jun. 18, 2026

(54) ADJUSTABLE SERVER MOUNTING EAR

(71) Applicant: Quanta Computer Inc., Taoyuan City (TW)

(72) Inventors: YAW-TZORNG TSORNG, Taoyuan City (TW); MING-LUNG WANG, Taoyuan City (TW); WEI-KANG TSAI, Taoyuan City (TW); WEI SHIH, Taoyuan City (TW)

(21) Appl. No.: 18/982,942

(22) Filed: Dec. 16, 2024

(51) Int. Cl. H05K 7/14

(52) U.S. Cl. CPC H05K 7/1489

(57) ABSTRACT

A mounting device for adjustably mounting hardware equipment to a mounting structure is provided. The mounting device may include one or more rails coupled to at least one side of the mountable hardware equipment, wherein each of the one or more rails includes a plurality of stop areas with one or more stop surfaces; one or more mounting ears that each comprise a mounting pin; and a latch comprising one or more stop parts. The latch may be configured to cause the one or more stop parts to interface with the one or more stop surfaces, arresting the position of the mountable hardware equipment. By applying pressure to the latch, it can compress and slide to a desired installation depth. When pressure is released, the latch can expand in a vertical direction and engage the stop parts with the stop surfaces to fix the hardware in position.

### FIELD OF THE INVENTION

The present disclosure relates generally to a hardware mounting device, and more specifically, to a hardware mounting device with an adjustable mounting depth.

### BACKGROUND OF THE INVENTION

Hardware mounting devices, such as mounting devices for computing systems, typically have fixed mounting ears, meaning that the hardware has a fixed installation depth based on the chassis of the hardware itself and the initial position of the fixed mounting ears. The fixed installation depth is predetermined by the manufacturer of the hardware or the mounting environment and can be difficult or even impossible to adjust in the field. Furthermore, it is difficult to adjust the mounting of current hardware equipment without the appropriate tools.

Edge servers, such as those used in the 5G wireless communications market, are particularly prone to this problem. Other non-server rack-mount equipment, such as ethernet switches and storage devices, also may encounter this issue. Many mounting structures used in edge systems are of varying size, specification, and depth. With the increasing adoption of 5G communications systems, there is a need in the art for systems, devices, and methods to allow for more flexible hardware mounting.

Due to the changing size of various hardware devices, especially rack-mount computing systems, mechanisms that allow for an adjustable installation depth are desirable.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system comprising a computing device having a first depth D1 and two lateral sides extending between a front area and a rear area is provided. The system may include a mounting area flexibly configured to support the computing device and a rail fixedly positioned along one of the two lateral sides. The rail may also include a plurality of position stops that includes a first position stop and a second position stop. The first position stop may be closer to the front area to accommodate the first depth D1 of the computing device, and the second position stop may be closer to the rear area. A mounting ear may be movably coupled to the rail. This mounting ear may be movable along the rail between the first position stop and the second position stop. The mounting ear may structurally support the computing device when in the first position stop.

In a further aspect of the present disclosure, the computing system may further comprise a mounting post fixedly mounted between the mounting ear and the mounting area.

According to a configuration of the above implementation, another rail may be fixedly positioned along another one of the two lateral sides. The other rail may be generally identical to the rail. The other rail can have another mounting ear that is generally identical to the mounting ear.

According to another configuration of the above implementation, the mounting ear may have a first side and a second side. The first side may be generally parallel to the rail, and the second side may extend generally perpendicular to the rail.

According to another configuration of the above implementation, each center with a spring joint may be configured to exert a force when uncompressed to cause each latch to expand in a vertical direction.

In a further aspect of the present disclosure, the second side can be fixedly mounted to a mounting post.

According to a configuration of the above implementation, each position stop of the plurality of position stops can include a stop surface adjacent to a stop part.

According to another configuration of the above implementation, the computing system may further comprise a latch mechanism that secures the mounting ear in a respective one of the plurality of stops. The latch mechanism can include a latch holder that is inserted between adjacent stop parts of the plurality of position stops.

According to another configuration of the above implementation, the latch holder may include a first latch holder and a second latch holder. The first latch holder may be inserted between top stop parts and the second latch holder may be inserted between bottom stop parts.

According to another configuration of the above implementation, the computing system may be configured so that the latch holder releases the mounting ear from a respective one of plurality of position stops in response to receiving a force oriented generally perpendicular to the rail.

According to another configuration of the above implementation, the computing device may be an edge server.

In a further aspect of the present disclosure, the computing device may be a rack-mount server.

According to certain aspects of the present disclosure, a method of mounting hardware equipment comprising exerting a force oriented generally perpendicular to at least one rail to cause at least one latch to engage a center and compress in a vertical direction is provided. The method may further include adjusting the hardware equipment to a desired depth within a mounting structure and adjusting at least one mounting ear coupled to the at least one rail to a desired position. After adjustment, the at least one stop part of the at least one latch may be aligned at least one stop surface of the at least one rail. When pressure is released from the at least one stop part of the at least one latch, the latch will expand in a vertical direction and cause the at least one stop part to engage the at least one stop surface. To fix the hardware equipment in the mounting structure at the desired depth at least one mounting pin may be inserted into at least one mounting post and the at least one mounting ear.

In a further aspect of the present disclosure, the mountable hardware equipment can be a rack-mount computing device.

According to a configuration of the above implementation, the rack-mount computing device can be an edge server.

According to a configuration of the above implementation, the rack-mount computing device can be a network switch.

According to another configuration of the above implementation, the mounting structure can be a rack-mount server cabinet.

According to a further configuration of the above implementation, the rack-mount server cabinet may be deployed within a data center or computing server system.

According to a further configuration of the above implementation, the rack-mount server cabinet may have a first depth D1 that is less than a second depth D2 of the rack-mount computing server.

According to certain aspects of the present disclosure a computing system is provided. The computing system may include a mounting area flexibly configured to support a computing device. The mounting area may have two lateral sides extending between a front area and a rear area. The computing device can be either a first computing device or a second computing device, with the first computing device having a first depth D1 that is greater than a second depth D2 of the second computing device. The computing system may include a rail fixedly positioned along one of the two lateral sides. The rail may include a plurality of position stops that includes a first position stop and a second position stop. The first position stop can be closer to the front area to accommodate the first depth D1 of the first computing device. The second position stop can be closer to the rear area to accommodate the second depth D2 of the second computing device. The computing system may also include a mounting ear movably coupled to the rail and fixedly coupled to the computing device. The mounting ear may be movable along the rail between the first position stop and the second position stop. The mounting ear may also structurally support the first computing device when in the first position stop and structurally support the second computing device in the second position stop.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present disclosure, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is an isometric view showing hardware equipment mounted in a mounting cabinet, according to certain aspects of the present disclosure.

FIG. 2 is a detailed view showing one of the mounting ears of the hardware equipment, according to certain aspects of the present disclosure.

FIG. 3 is another detailed view showing one of the mounting ears of the hardware equipment, according to certain aspects of the present disclosure.

FIG. 3A is a side view of a mounting ear and mounting pin interfacing with a latch, according to certain aspects of the present disclosure.

FIG. 4A is an isometric view of hardware equipment with an adjustable mounting depth, according to certain aspects of the present disclosure.

FIG. 4B is a top view of hardware equipment being adjusted to an adjustable mounting depth, according to certain aspects of the present disclosure.

FIG. 4C is a side view of a latch being engaged, according to certain aspects of the present disclosure.

FIG. 5A is an isometric view of hardware equipment with an adjustable mounting depth, according to certain aspects of the present disclosure.

FIG. 5B is a top view of hardware equipment with an adjustable mounting depth, according to certain aspects of the present disclosure.

FIG. 5C is a side view of a latch and mounting ear with an adjustable mounting depth, according to certain aspects of the present disclosure.

FIG. 6A is an isometric view of hardware equipment with an adjustable mounting depth, according to certain aspects of the present disclosure.

FIG. 6B is a top view of hardware equipment with an adjustable mounting depth, according to certain aspects of the present disclosure

FIG. 6C is a side view of a latch and mounting ear with an adjustable mounting depth, according to certain aspects of the present disclosure.

### DETAILED DESCRIPTION

Systems, devices, and methods for mounting hardware at an adjustable depth in a mounting structure are provided. The systems, devices, and methods include one or more mounting ears coupled to the hardware equipment and one or more rails coupled to the hardware equipment. The one or more rails may include a latch with stop parts configured to interface with one or more stop surfaces of the rail. The latch may be compressed, and the equipment slid to a desired depth in a mounting structure configured to interface with the one or more rails and the one or more mounting ears. One or more mounting pins may be used to securely fix the hardware equipment in place.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

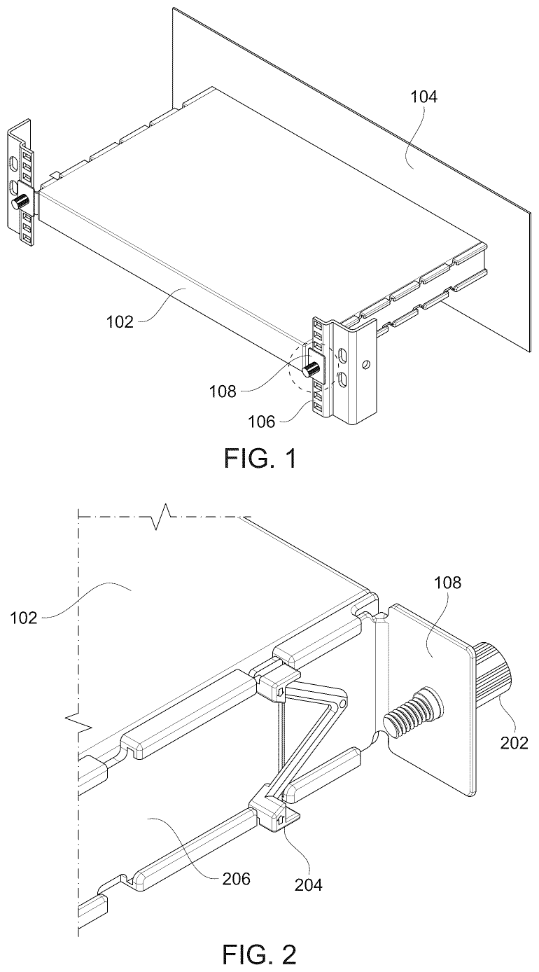

Referring to FIG. 1, an isometric view of hardware equipment 102 in a mounting structure 104 is provided. The hardware equipment 102 can be a computing server, an edge server, another rack-mount computing component like a storage system, or any other piece of equipment configured to be mounted in a mounting structure 104. The mounting structure 104 can be a server cabinet, such as a standard rack-mount server cabinet. The mounting structure can also be any other structure capable of having equipment mounted in it.

The hardware equipment 102 may be configured to be mounted to one or more mounting posts 106 in the mounting structure 104 by one or more mounting ears 108. The mounting posts 106 may include a plurality of holes, slots, or other receptacles for screws, pins, nails, or other fasteners of the mounting ear 108 to interface with. The mounting posts 106 may also use a toolless clip mechanism, a magnetic fastener, or an adhesive material to interface with the mounting ear 108. In some example embodiments, the mounting posts 106 may be coupled to the one or more mounting ears 108, which may be configured to interface with the hardware equipment 102. In some other example embodiments, the mounting posts 106 may be movable.

As shown in FIG. 1, the hardware equipment 102 may be installed at the maximum possible depth in the mounting structure 104. This represents the deepest point at which the mounting ears 108 can interface with the mounting posts 106. In some example embodiments of the present disclosure, this maximum depth may be between 0 inches (0 centimeters) to 50 inches (127 centimeters) deep.

Referring to FIG. 2, a detailed view showing one of the mounting ears 108 of the hardware equipment is provided, according to certain aspects of the present disclosure. The mounting ears 108 may include a hole, slot, receptacle, or other mechanism to accept a mounting pin 202. The mounting pin 202 may be a screw, pin, nail, or other fastener. The mounting pin 202 may include a cap allowing it to be inserted and tightened by hand or by a tool, and it may include protective or adhesive coatings. The mounting pin 202 may also have a coating designed to decrease or increase friction with the mounting ear 108. In some example embodiments, the mounting pin 202 may be used to fix the mounting ear 108 to the hardware equipment 102.

In some configurations, there may be one or more latches 204 and one or more rails 206 coupled to the hardware equipment 102. The latch 204 may be coupled to the rails 206 by a fixed center. The latch 204 may be a Y-shaped or triangular assembly with protruding sections designed to rotate or move around the fixed center. The latch 204 may be configured to interface with one or more sections of the rails 206. The latch 204 may be made from plastic, carbon fiber, aluminum, a rubber material, a steel material such as hot-dip zinc-coated galvanized steel (SGCC), or any other material or composite of materials.

The hardware equipment 102 may include one or more rails 206 located on a side or edge of the hardware equipment 102. The rails 206 may be coupled to the hardware equipment 102 by a screw, nail, pin, or other fastener. The rails 206 may also be coupled to the hardware equipment 102 by adhesive, magnetic, chemical, or metallurgical means. The rails 206 may be made from plastic, aluminum, a steel material such as hot-dip zinc-coated galvanized steel (SGCC), or any other material. The rails 206 may also be coupled to the mounting structure.

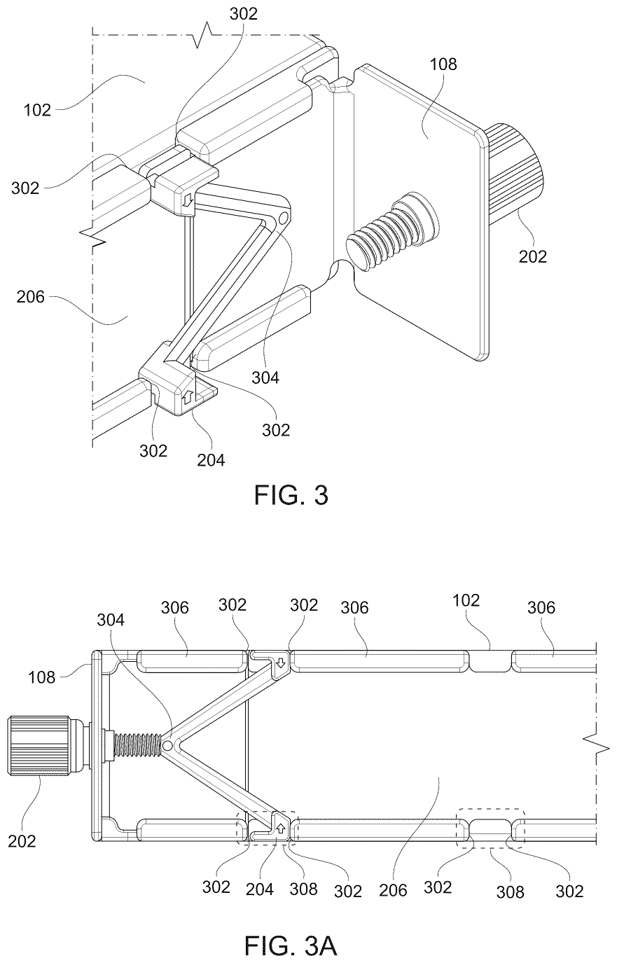

Referring to FIG. 3, another detailed view showing one of the mounting ears of the hardware equipment according to certain aspects of the present disclosure is provided. The rails 206 may include a plurality of stop surfaces 302, which comprise protrusions, raised portions, slots, or areas configured to interface with the latch 204.

The latch 204 may include a fixed center 304. In some embodiments, the fixed center 304 may be coupled to the rail 206. The fixed center 304 may be a point in a center of the protruding sections of the latch 204 that is made from a flexible material, or a material with a low elastic modulus. This may allow the protruding sections of the latch 204 to rotate or otherwise move around the fixed center 304. The fixed center 304 may also comprise a joint allowing the protruding sections of the latch 204 to rotate or otherwise move around the fixed center 304. The joint can be a spring joint, a revolute or pin join, a ball joint, a universal joint, a hinge joint, a saddle joint, a gear, or any other sort of mechanical linkage that allows for rotational motion in a two-dimensional plane. The fixed center 304 may also be a magnetic linkage that allows for rotational motion.

Referring to FIG. 3A, a side view of a mounting ear and mounting pin interfacing with a latch according to certain aspects of the present disclosure is provided. The stop surfaces 302 may be at one or more ends of stop areas 306, which may be parts of the rails 206 that are designed to withstand or otherwise hold interfacing parts in a fixed position with respect to the rails. The plurality of stop areas 306 may be disposed to create a plurality of slots or receptacles along a length of a rail 206, which may be of a standardized size. In some embodiments of the present disclosure, the plurality of stop areas 306 are disposed in two rows across two edges of the rail 206, creating a parallel plurality of slots along a length of the rail 206. The plurality of stop areas 306 may be configured to receive a plurality of stop parts 308 of the latch 204. The stop areas 306 allow for the latch 204 to be fixed in certain positions with respect to the rails 206. This is done by the interfacing of a stop part 308 with the stop surface 302 of the stop area 306. The stop part 308 may interface with the stop surface 302 through friction, adhesion, cohesion, magnetism, or another mechanism. The stop surface 302 acts as resistance against the stop part 308, holding it in place between a plurality of stop areas 306. In some embodiments, the stop surfaces 302 may include mechanical mechanisms such as clips, ball bearings, or springs to hold the stop parts 308 in place and/or allow for the disengagement of the stop parts 308 with the stop surfaces 302 in response to a stimulus.

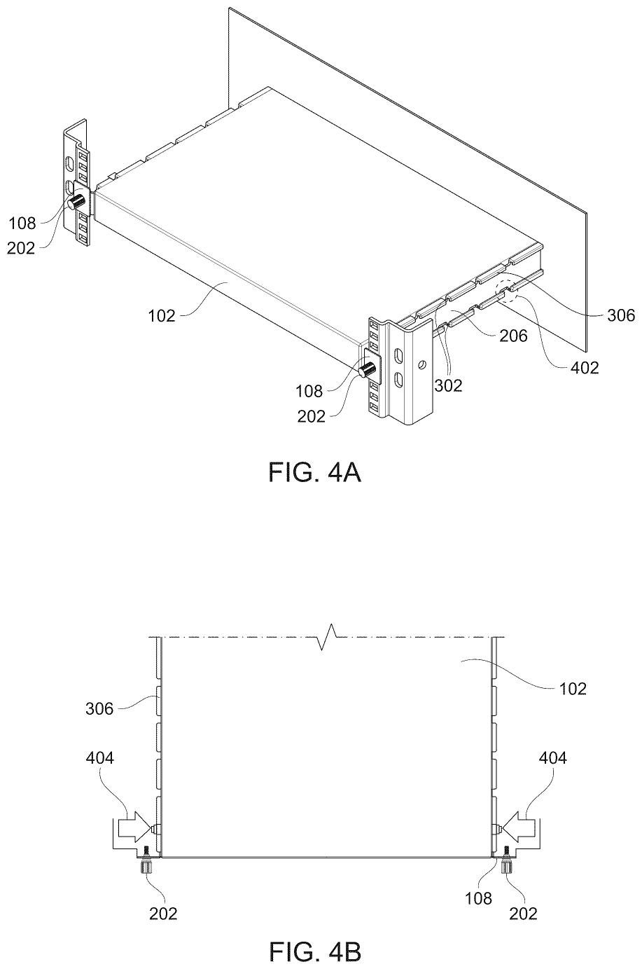

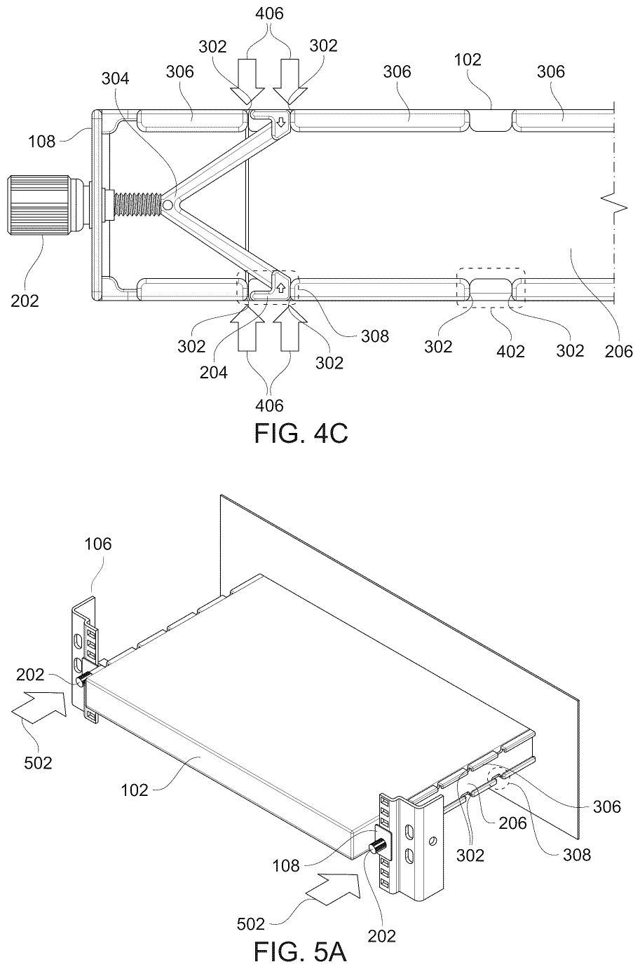

Referring to FIG. 4A, an isometric view of hardware equipment with an adjustable mounting depth, according to certain aspects of the present disclosure is provided. This view illustrates how the hardware equipment 102 may include one or more rails 206 that each include a plurality of stop areas 306. The plurality of stop areas 306 and stop surfaces 302 may be disposed to create a plurality of slots such as slot 402. In FIG. 4A, the example hardware equipment 102 is displayed as mounted in the mounting structure at its maximum depth. Therefore, the latch is disposed within the slots of the stop areas 306 farthest from the mounting structure. To fix the hardware equipment 102 in place, the mounting pins 202 are fixed within the mounting ears 108.

Referring to FIG. 4B, a top view of hardware equipment being adjusted to an adjustable mounting depth according to certain aspects of the present disclosure is provided. The adjustment method includes locating the position 404 of the latch 204 with respect to the rails 206. The position 404 of the latch 204 represents the depth of the hardware equipment 102 in the mounting structure.

Referring to FIG. 4C a side view of a latch 204 being engaged according to certain aspects of the present disclosure is provided. The adjustment method may include applying pressure 406 or another stimulus in a vertical direction with respect to the stop parts 308 of the latch 204. When pressure 406 is applied to the stop parts 308 of the latch 204, the protruding sections of the latch 204 may be caused to rotate or otherwise move about the fixed center 304. This can cause the stop parts 308 of the latch 204 to disengage from the stop surfaces 302 of the stop areas 306. This process can be facilitated by ball bearings, lubricants, clips, or other mechanisms of the stop surfaces 302. Once the stop parts 308 are disengaged from the stop surfaces 302, the latch 204, and therefore the coupled hardware equipment 102, may be moved in a horizontal direction with respect to the rails 206. This allows for an adjustable mounting depth.

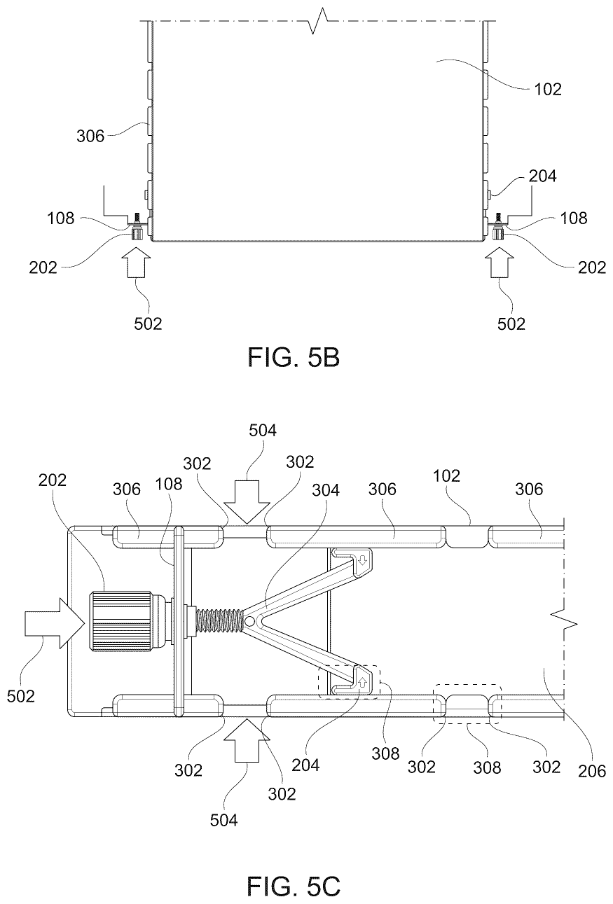

Referring to FIG. 5A, an isometric view of hardware equipment with an adjustable mounting depth, according to certain aspects of the present disclosure, is provided. The adjustment method may include moving the hardware equipment 102 in a horizontal plane 502 to adjust the mounting depth. Once the latch 204 has been disengaged from the stop surfaces 302, the hardware equipment 102 can be moved to a desired depth in the horizontal plane 502. This may allow for hardware equipment with a chassis depth greater than the depth of the mounting structure to still be mounted. For example, in FIG. 5A, the hardware equipment 102 is too long to entirely fit in the depth of the mounting structure based on the position of the mounting posts 106. Using the systems and methods herein, however, the mounting ears 108 have been moved to a position to allow the hardware equipment 102 to be mounted in the mounting structure.

Referring to FIG. 5B, a top view of hardware equipment with an adjustable mounting depth according to certain aspects of the present disclosure is provided. The top view illustrates how the latch 204 has allowed the depth of the mounting ears 108 to be changed with respect to the hardware equipment 102. By moving the mounting ears in a horizontal direction in the horizontal plane 502, the hardware equipment 102 can be mounted at a depth differing from that of the overall depth of the chassis of the hardware equipment 102.

Referring to FIG. 5C, a side view of a latch and mounting ear with an adjustable mounting depth according to certain aspects of the present disclosure is provided. During the depth adjustment procedure, the latch will be disengaged from the stop surfaces 302 by the horizontal force 504. While disengaged, the latch 204 will compress in a vertical direction with respect to the rails 206 and fit in between the stop areas 306. This may allow the latch 204 to travel freely within the rail 206. Travel within the rail 206 may be facilitated by lubricants, rollers, or other materials on the portions of the stop parts 308 that come into contact with portions of the stop areas 306. Once the stop parts 308 are aligned with slots created by stop surfaces 302 of the stop areas 306, the fixed center 304 may release and reengage the stop parts 308 302 with the stop surfaces 302.

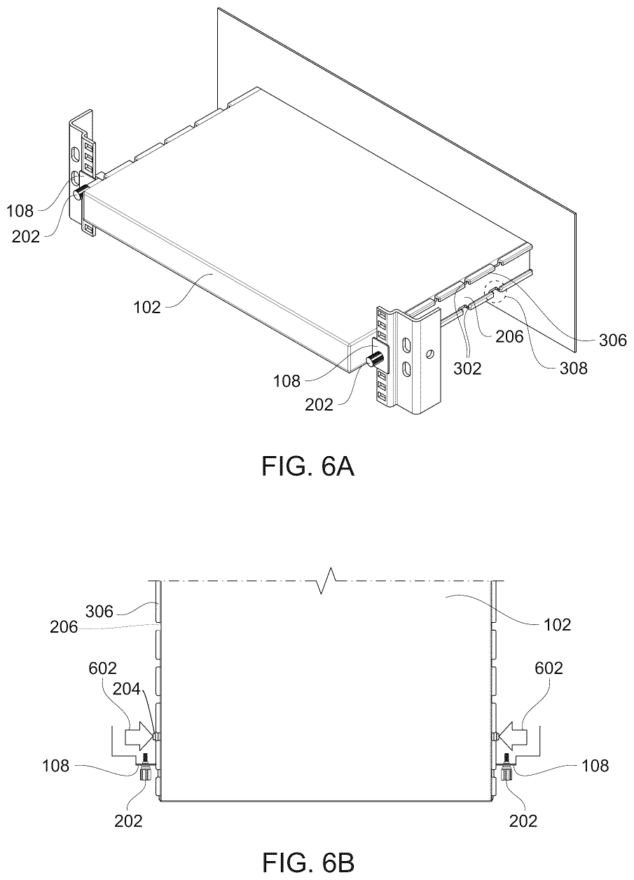

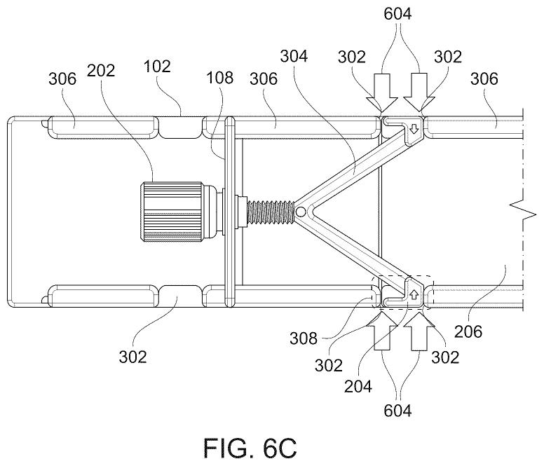

Referring to FIG. 6A, an isometric view of hardware equipment with an adjustable mounting depth according to certain aspects of the present disclosure is provided. FIG. 6A shows the hardware equipment 102 once it has been fixed at an adjusted depth within the mounting structure. In this example embodiment, the mounting ear 108 has been moved to allow the hardware equipment 102 to be mounted at an adjusted depth. The mounting pin 202 has been inserted into the mounting ears 108 to fix the hardware equipment 102 in place.

Referring to FIG. 6B, a top view of hardware equipment with an adjustable mounting depth, according to certain aspects of the present disclosure, is provided. FIG. 6B gives more detail to the adjusted mounting depth of FIG. 6A. As shown, the latch 204 has been adjusted to be in position 602 on the rails 206. This has moved the mounting ears 108 further back on the hardware equipment 102, allowing for it to be mounted at desired depth. The mounting pins 202 have been inserted into the mounting ears 108 to fix the hardware equipment 102 at the desired mounting depth.

Referring to FIG. 6C, a side view of a latch and mounting ear with an adjustable mounting depth according to certain aspects of the present disclosure is provided. In this example embodiment, the stop parts 308 of the latch 204 have been aligned with the slot 604 created by the stop surface 302 and the stop areas 306. In some embodiments, the fixed center 304 may cause the protruding portions of the latch 204 to extend in a vertical direction. This may be done with a spring, elastic material, motor, or other mechanism. When extended, the latch 204 may interface with the stop surfaces 302 of the stop areas 306, causing portions of the latch 204 to interface with the slot 604. This will arrest the motion of the mounting ear 108, allowing for the installation depth of the hardware equipment 102 to be adjusted to a desired depth. In some embodiments, the slot 604 may be a gear or tooth mechanism instead of a gap between the stop areas 306. In some other embodiments the slot 604 may be an adhesive or magnetic portion of the stop areas 306.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the disclosure may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system comprising:
a computing device having a first depth D1 and two lateral sides extending between a front area and a rear area;
a mounting area flexibly configured to support the computing device;
a rail fixedly positioned along one of the two lateral sides, the rail including a plurality of position stops that includes a first position stop and a second position stop, the first position stop being closer to the front area to accommodate the first depth D1 of the computing device, the second position stop being closer to the rear area; and
a mounting ear movably coupled to the rail, the mounting ear being movable along the rail between the first position stop and the second position stop, the mounting ear structurally supporting the computing device when in the first position stop.

2. The computing system of claim 1, further comprising a mounting post fixedly mounted between the mounting ear and the mounting area.

3. The computing system of claim 1, wherein another rail is fixedly positioned along another one of the two lateral sides, the another rail being generally identical to the rail, the another rail having another mounting ear that is generally identical to the mounting ear.

4. The computing system of claim 1, wherein the mounting ear has a first side and a second side, the first side being generally parallel to the rail, the second side extending generally perpendicular to the rail.

5. The computing system of claim 4, wherein the second side is fixedly mounted to a mounting post.

6. The computing system of claim 1, wherein each position stop of the plurality of position stops includes a stop surface adjacent to a stop part.

7. The computing system of claim 6, further comprising a latch mechanism that secures the mounting ear in a respective one of the plurality of stops, the latch mechanism including a latch holder that is inserted between adjacent stop parts of the plurality of position stops.

8. The computing system of claim 7, wherein the latch holder includes a first latch holder and a second latch holder, the first latch holder being inserted between top stop parts and the second latch holder being inserted between bottom stop parts.

9. The computing system of claim 7, wherein, in response to receiving a force oriented generally perpendicular to the rail, the latch holder releases the mounting ear from a respective one of plurality of position stops.

10. The computing system of claim 1, wherein the computing device is an edge server.

11. The computing system of claim 10, wherein the computing device is a network switch.

12. The computing system of claim 10, wherein the mounting area is a rack-mount server cabinet.

13. A method of mounting hardware equipment comprising:
exerting a force oriented generally perpendicular to at least one rail to cause at least one latch to engage a center and compress in a vertical direction;
adjusting the hardware equipment to a desired depth within a mounting area;
adjusting at least one mounting ear coupled to the at least one rail to a desired position
aligning at least one stop part of the at least one latch with at least one stop surface of the at least one rail;
releasing pressure from the at least one stop part of the at least one latch so as to cause the latch to expand in a vertical direction and cause the at least one stop part to engage the at least one stop surface; and
inserting at least one mounting pin into at least one mounting post and the at least one mounting ear to fix the hardware equipment in the mounting area at the desired depth.

14. The method of claim 13, wherein the hardware equipment is a rack-mount computing device.

15. The method of claim 14, wherein the rack-mount computing device is an edge server.

16. The method of claim 14, wherein the rack-mount computing device is a network switch.

17. The method of claim 14, wherein the mounting area is a rack-mount server cabinet.

18. The method of claim 17, wherein the rack-mount server cabinet is deployed within a data center or computing server system.

19. The method of claim 17, wherein the rack-mount server cabinet has a first depth D1 that is less than a second depth D2 of the rack-mount computing server.

20. A computing system comprising:
a mounting area flexibly configured to support a computing device, the mounting area having two lateral sides extending between a front area and a rear area, the computing device being either a first computing device or a second computing device, the first computing device having a first depth D1 that is greater than a second depth D2 of the second computing device;
a rail fixedly positioned along one of the two lateral sides, the rail including a plurality of position stops that includes a first position stop and a second position stop, the first position stop being closer to the front area to accommodate the first depth D1 of the first computing device, the second position stop being closer to the rear area to accommodate the second depth D2 of the second computing device; and
a mounting ear movably coupled to the rail and fixedly coupled to the computing device, the mounting ear being movable along the rail between the first position stop and the second position stop, the mounting ear structurally supporting the first computing device when in the first position stop, the mounting ear structurally supporting the second computing device in the second position stop.
